(19) United States
(12) Patent Application Publication
(10) Pub. No.: US 2012/0223354 A1
(43) Pub. Date: Sep. 6, 2012

(54) SEMICONDUCTOR TWO-PHOTO DEVICE

(75) Inventors: Alex Hayat, Karmiel (IL); Meir Orenstein, Haifa (IL); Amir Nevet, Haifa (IL)

(73) Assignee: TECHNION-RESEARCH & DEVELOPMENT FOUNDATION, Haifa (IL)

(21) Appl. No.: 13/502,653

(22) PCT Filed: Oct. 17, 2010
(86) PCT No.: PCT/IL10/00847

§ 371 Date: Apr. 18, 2012

Related U.S. Application Data
(60) Provisional application No. 61/252,676, filed on Oct. 18, 2009.

(51) Int. Cl. H01L 33/60; H01L 33/58

(52) U.S. Cl. 257/98; 438/31; 257/E33.072; 257/E33.067

(57) ABSTRACT

A semiconductor, room-temperature, electrically excited, two-photon device with thick optically active layer is provided. The intrinsic AlGaAs active layer is sandwiched between two intrinsic graded waveguide layers having increased aluminum concentration at increased distance from the active layer. The waveguide structure is sandwiched between two cladding layers of high aluminum concentration, n and p doped respectively. The structure is epitaxially grown on a substrate and further comprises other layers such as buffer, graded layers and contact layers. An etched ridge provides lateral confinement for light. The device provides two-photons gain and may be used in light sources, optical amplifiers, pulse compressors and lasers.

### FIELD OF THE INVENTION

A semiconductor, room-temperature, electrically excited, two-photon device with thick optically active layer.

### BACKGROUND OF THE INVENTION

The present invention, in some embodiments thereof, relates to a semiconductor, room-temperature, electrically excited, two-photon emitting device having extended physical dimensions, and its application.

The phenomenon of two-photon gain (TPG), in which photons are amplified in pairs, was proposed in the early days of the laser for the development of unique quantum oscillators, generating giant pulses and enabling wide frequency tunability. Two-photon amplifiers and lasers (TPL) should also exhibit exceptional classical behavior such as bi-stability, as well as quantum properties including squeezing due to the inherent nonlinearity of the process; however the realization of such oscillators proved to be very difficult. All previous TPLs were realized in dilute discrete-level atomic systems in a maser-like configuration, resulting in relatively low powers and requiring sophisticated designs.

Quantum entangled photon pairs can be used for quantum information processing, including quantum cryptography, quantum computing and quantum teleportation, as described, for example, by C. Bennett and S. J. Weisner, Phys. Rev. Lett. 69, 2881 (1992); P. Kumar et al, Quantum Inf. Process. 3, 215 (2004); Z. D. Walton et al, Phys. Rev. A, 67, 062309 (2003); and J. F. Clauser et al, Phys. Rev. Lett. 23, 880 (1969). Quantum entangled photon pairs can also be used for very low noise spectroscopy (including in vivo spectroscopy) and microscopy, as described, for example, by Saleh et al., Phys. Rev. Lett. 80, 3483 (1998) and by U.S. Pat. No. 5,796,477 to Teich et al.

Pairs of quantum entangled photons can be produced by using two photon emission from certain atomic radiative cascades, as described, for example, by A. Aspect, P. Gragnier and G. Roger, Phys. Rev. Lett. 47, 460 (1981), but these sources suffer from low brightness and polarization degradation caused by the atomic recoil.

Solid state sources of entangled photon pairs, based on parametric down conversion (PDC) of pump photons, for example in non-centrosymmetric crystals with second-order optical nonlinearity, have higher emission rates, and are described, for example, by P. G. Kwiat et al, Phys. Rev. Lett. 75, 4337 (1995), by M. Pelton et al, Opt. Express 12, 3573 (2004), and by X. Li et al, Phys. Rev. Lett. 94, 053601 (2005). But these sources have relatively low efficiency because they use post-selection or spatial filtering, and are based on a third-order (in the fine structure constant .alpha.) non-resonant process in the time-dependent perturbation theory. PDC sources typically require pump lasers of high power, are bulky, and use exotic materials. The pump lasers typically used cost over $100,000.

Semiconductor quantum dots can also produce pairs of entangled photons, by single photon emission from pairs of entangled electrons, as described for example by N. Akopian et al, Phys. Rev. Lett. 96, 130501 (2006), and they are more efficient than PDC sources. However, quantum dot sources have low generation rates, their emission wavelengths are not tunable, currently only optical excitation is implemented and they require cryogenic temperatures, typically lower than 20 K. An article by Rupert Goodwins, dated Jan. 11, 2006 and downloaded from the internet at http://news.zdnet.com/2100-1009.sub.—22-6026098.html, on Nov. 18, 2007, quotes Andrew Shields, head of the Quantum Information group at Toshiba Research Europe, as saying that there is no reason in principle why quantum dots could not produce entangled pairs of photons at room temperature, but states that there are still challenges to be overcome before achieving such a device.

Two-photon amplifiers and lasers are described, for example, by C. N. Ironside, IEEE J. of Quantum Elect. 28, 842 (1992); C. Z. Ning, Phys. Rev. Lett. 93, 187403 (2004); D. H. Marti et al, IEEE J. of Quantum Elect. 39, 1066 (2003); and D. R. Heatley et al, Opt. Lett. 18, 628 (1993). Heatley et al describe using two-photon amplifiers and for pulse generation, because the gain in two-photon lasers/amplifiers, in contrast to conventional single photon lasers, is nonlinear, depending on the amplitude of the light wave.

Two photon absorption in semiconductors has been investigated, for example, by V. Nathan et al, J. Opt. Soc. Am. B 2, 294 (1985); C. C. Lee and H. Y. Fan, Phys. Rev. B 9, 3502 (1974); N. G. Basov et al, J. Phys. Soc. Japan Suppl. 21, 277 (1966); D. C. Hutchings and E. W. Van Stryland, J. Opt. Soc. Am. B 9, 2065 (1992); and M. Sheik-Bahae et al, IEEE J. Quantum Electron. 27, 1296 (1991).

General background and further references may be found in:

Physical review letters paper: PRL 102, 183002 (2009) 8 May 2009, titled “Electrically Induced Two-Photon Transparency in Semiconductor QuantumWells” to Alex Hayat, Amir Nevet, and Meir Orenstein;

in “Observation of two-photon emission from semiconductors” to Alex Hayat, Pavel Ginzburg and Meir Orenstein; which was published online: 2 Mar. 2008; doi:10.1038/nphoton.2008.28;

and in N. Kaminski, A. Hayat, P. Ginzburg, and M. Orenstein, IEEE Photon. Technol. Lett. 21, 173 (2009).

United States Patent Application 20090135870; titled “Light source based on simultaneous Two-Photon emission”; to Hayat; Alex; et al; discloses a semiconductor device which produces at least 1 W/m2 two photon emission power per area, when operating at one or more temperatures greater than 20K.

The disclosures of the above mentioned documents are incorporated herein by reference.

### SUMMARY OF THE INVENTION

The present invention, in some embodiments thereof, relates to a semiconductor, room-temperature, electrically excited, two-photon emitting device having extended physical dimensions, and its application.

The present invention demonstrates two-photon gain (TPG) in a solid-state device. Using the inventive device, TPG was directly observed and characterized in electrically-pumped room-temperature semiconductor devices in excellent agreement with the theoretical models. Achieving two-photon gain in solids, in particular in semiconductors, is similar to the evolution of the maser to a diode laser, with the benefits of orders of magnitude higher emitter densities, miniature fabrication technology, and electrical pumping. The present invention paves the way for implementation of compact two-photon sources with applications for ultrafast science, bio-imaging, spectroscopy, quantum information and fundamental light-matter interaction studies.

In an embodiment of the invention, a semiconductor, room-temperature, electrically excited, two-photon device with thick optically active layer is provided, wherein the intrinsic AlGaAs active layer is sandwiched between two intrinsic graded waveguide layers having increased aluminum concentration at increased distance from the active layer. The waveguide structure is sandwiched between two cladding layers of high aluminum concentration, n and p doped respectively. The structure is epitaxially grown on a substrate and further comprises other layers such as buffer, graded layers and contact layers. An etched ridge provides lateral confinement for light. The device provides two-photons gain and may be used in light sources, optical amplifiers, pulse compressors and lasers.

It is one aspect of the invention to provide a semiconductor, room-temperature, electrically excited, two-photon emitting device having an optical active layer within a wave-guiding structure, wherein the thickness of the optical active layer is more than 10 percent of the effective optical mode dimension in the direction normal to said optical active layer.

In some embodiments the thickness of the optical active layer is more than 20 percent of the effective optical mode dimension in the direction normal to said optical active layer.

It is another aspect of the current invention to provide a bright, broad spectrum to light source based on two-photon spontaneous emission from a semiconductor, room-temperature, electrically excited, two-photon emitting device having an optical active layer within a wave-guiding structure, wherein the thickness of the optical active layer is more than 10 percent of the effective optical mode dimension in the direction normal to said optical active layer.

It is yet another aspect of the current invention to provide a room-temperature, semiconductor, electrically excited, two-photon gain device having an optical active layer within a wave-guiding structure, wherein the thickness of the optical active layer is more than 10 percent of the effective optical mode dimension in the direction normal to said optical active layer. In some embodiments, the gain device has non-linear gain. In some embodiments the non-linear gain device is used as pulse compressor.

It is yet another aspect of the current invention to provide a room-temperature, semiconductor, electrically excited, two-photon laser device having an optical active layer within a wave-guiding structure, wherein the thickness of the optical active layer is more than 10 percent of the effective optical mode dimension in the direction normal to said optical active layer.

In some embodiments the two-photon laser is seeded by a laser external to the cavity of the two-photon laser.

In some embodiments the two-photon laser further comprises a one-photon gain internal to the cavity of the two-photon laser.

It is yet another aspect of the current invention to adopt a room-temperature, semiconductor, electrically excited, two-photon device to desired photon energy by adjusting the band-gap of the optically active layer of the device to be at least 1.5 percents lower than the sum energies of the two emitted photons.

In some embodiments the band-gap of the optically active layer of the device is no more than 7 percents lower than the sum energies of the two emitted photons.

It is yet another aspect of the current invention to provide a method of manufacturing a semiconductor, room-temperature, electrically excited, two-photon device. The method comprises at least the steps of:
a) Epitaxially growing a first, doped, cladding layer.
b) Epitaxially growing a first, graded wave-guiding layer.
c) Epitaxially growing an intrinsic optically active layer.
d) Epitaxially growing a second, graded wave-guiding layer.
e) Epitaxially growing a second cladding layer doped with opposite doping type as the first cladding layer.
f) Etching a ridge in the structure to create a linear wave-guide; and
g) Connecting leads for providing current through the optically active layer, wherein the thickness of the optically active layer is at least 10 percent of the thickness of the optical mode confined by the wave-guiding layers.

In some embodiments the thickness of said optically active layer is at least 20 percent of the thickness of the optical mode confined by the wave-guiding layers.

In some embodiments the thickness of said optically active layer is at least 40 percent of the thickness of the optical mode confined by the wave-guiding layers.

In some embodiments the substrate is doped GaAs substrate.

In some embodiments the first cladding layer is Si doped AlGaAs, and said second cladding layer is Zn doped AlGaAs.

In some embodiments the optically active layer is an intrinsic AlGaAs having Al concentration lower than Al concentration in said first and second cladding layers.

In some embodiments the method further comprises the step of: epitaxially grow on said substrate a Si doped buffer layer; epitaxially grow on said buffer layer a first Si doped graded layer; epitaxially grow on said second cladding layer a second Zn doped graded layer; and epitaxially grow on said second graded layer a Zn doped contact layer.

In some embodiments the thickness of said optically active layer is at least 0.2 microns.

In some embodiments the thickness of said optically active layer is at least 0.4 microns.

According to an exemplary embodiment of the invention, a semiconductor, room-temperature, electrically excited, two-photon device is provided, the device comprising: a substrate; a first doped cladding layer; a first graded wave-guiding layer adjacent to said first cladding layer; an intrinsic optically active layer adjacent to said first graded wave-guiding layer; a second graded wave-guiding layer adjacent to said optically active layer; a second cladding layer doped with opposite doping type as the first cladding layer adjacent to said second graded wave-guiding layer; a ridge etched in the structure to creating a linear wave-guide; and leads, capable of providing electrical current through said optically active layer, wherein the thickness of said optically active layer is at least 10 percent of the thickness of the optical mode confined by the wave-guiding layers.

In some embodiments the thickness of said optically active layer is at least 20 percent of the thickness of the optical mode confined by the wave-guiding layers.

In some embodiments the thickness of said optically active layer is at least 40 percent of the thickness of the optical mode confined by the wave-guiding layers.

In some embodiments the substrate is doped GaAs substrate.

In some embodiments the first cladding layer is Si doped AlGaAs, and said second cladding layer is Zn doped AlGaAs.

In some embodiments the optically active layer is an intrinsic AlGaAs having Al concentration lower than Al concentration in said first and second cladding layers.

In some embodiments the device is further comprising: Si doped buffer layer adjacent to said substrate; a first Si doped graded layer between said buffer layer and said first cladding layer; a second Zn doped graded layer adjacent to said second cladding layer; and a Zn doped contact layer.

In some embodiments the thickness of said optically active layer is at least 0.2 microns.

In some embodiments the thickness of said optically active layer is at least 0.4 microns.

In some embodiments at least one end of said linear wave-guide is coated with an anti-reflection coating, and said device is capable of producing broad spectrum infrared radiation by two-photon spontaneous when electrical current is applied between said leads.

In some embodiments both ends of said linear wave-guide are coated with an anti-reflection coating.

In some embodiments the second end of said linear wave-guide is coated with a high reflectance coating.

In some embodiments both end of said linear wave-guide are coated with an anti-reflection coating, and said device is capable of producing broad spectrum gain by two-photon stimulated emission when electrical current is applied between said leads.

In some embodiments the device is capable of producing non-linear gain of an input signal when said input signal is substantially at central wavelength of said broad spectrum gain.

In some embodiments the device is capable of producing pulse shortening when said input signal is in a form of a short pulse.

In some embodiments the device is further comprising two cavity mirrors, each positioned to reflect light back into one ends of said guide, such that the device is capable producing two-photon lasing when current is applied between said leads.

In some embodiments the device is further comprising a one-photon laser capable of producing coherent radiation, wherein said one-photon laser is external to the cavity formed by said two cavity mirrors and is capable of seeding said two-photon lasing action.

In some embodiments the device is further comprising a one-photon gain device internal to the cavity formed by said two cavity mirrors and is capable of seeding said two-photon lasing action.

Unless otherwise defined, all technical and scientific terms used herein have the same meaning as commonly understood by one of ordinary skill in the art to which this invention belongs. Although methods and materials similar or equivalent to those described herein can be used in the practice or testing of the present invention, suitable methods and materials are described below. In case of conflict, the patent specification, including definitions, will control. In addition, the materials, methods, and examples are illustrative only and not intended to be limiting.

### BRIEF DESCRIPTION OF THE DRAWINGS

Some embodiments of the invention are herein described, by way of example only, with reference to the accompanying drawings. With specific reference now to the drawings in detail, it is stressed that the particulars shown are by way of example and for purposes of illustrative discussion of the preferred embodiments of the present invention only, and are presented in the cause of providing what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention may be embodied in practice.

In the drawings:

FIG. 1 schematically shows a side cross-sectional view of an electrically driven semiconductor device for two photon emission, using quantum wells as known in the art.

FIG. 2 schematically depicts a side view cross section of a semiconductor, room-temperature, electrically excited, two-photon device having a thick optically active layer according to an exemplary embodiment of the current invention.

FIG. 3 schematically shows a perspective view of the device shown in FIG. 2 according to an exemplary embodiment of the current invention.

FIG. 4A schematically depicts a bright source of broad wavelength, infrared radiation according to an exemplary embodiment of the current invention.

FIG. 4B schematically depicts a bright source of broad wavelength, infrared radiation according to another exemplary embodiment of the current invention.

FIG. 4C schematically depicts a broad wavelength optical gain device according to an exemplary embodiment of the current invention.

FIG. 4D schematically depicts a non-linear optical amplifier and pulse compressor according to an exemplary embodiment of the current invention.

FIG. 5A schematically depicts an externally seeded two-photon laser according to an exemplary embodiment of the current invention.

FIG. 5B schematically depicts an internally seeded two-photon laser according to another exemplary embodiment of the current invention.

### DESCRIPTION OF PREFERRED EMBODIMENTS

Before explaining at least one embodiment of the invention in detail, it is to be understood that the invention is not necessarily limited in its application to the details set forth in the following description or exemplified by the Examples. The invention is capable of other embodiments or of being practiced or carried out in various ways.

The terms “comprises”, “comprising”, “includes”, “including”, and “having” together with their conjugates mean “including but not limited to”.

The term “consisting of” has the same meaning as “including and limited to”.

The term “consisting essentially of” means that the composition, method or structure may include additional ingredients, steps and/or parts, but only if the additional ingredients, steps and/or parts do not materially alter the basic and novel characteristics of the claimed composition, method or structure.

As used herein, the singular form “a”, “an” and “the” include plural references unless the context clearly dictates otherwise. For example, the term “a compound” or “at least one compound” may include a plurality of compounds, including mixtures thereof.

Throughout this application, various embodiments of this invention may be presented in a range format. It should be understood that the description in range format is merely for convenience and brevity and should not be construed as an inflexible limitation on the scope of the invention. Accordingly, the description of a range should be considered to have specifically disclosed all the possible sub-ranges as well as individual numerical values within that range.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable sub-combination or as suitable in any other described embodiment of the invention. Certain features described in the context of various embodiments are not to be considered essential features of those embodiments, unless the embodiment is inoperative without those elements.

In discussion of the various figures described herein below, like numbers refer to like parts. The drawings are generally not to scale. For clarity, non-essential elements were omitted from some of the drawing.

United States patent application 20090135870; titled “Light source based on simultaneous Two-Photon emission”; to Hayat; Alex; et al; discloses a semiconductor device which produces at least 1 W/m2 two photon emission power per area, when operating at one or more temperatures greater than 20 K. The disclosed device is based on a heterostructure comprising at least one quantum well. The application further details application for the disclosed two-photon gain.

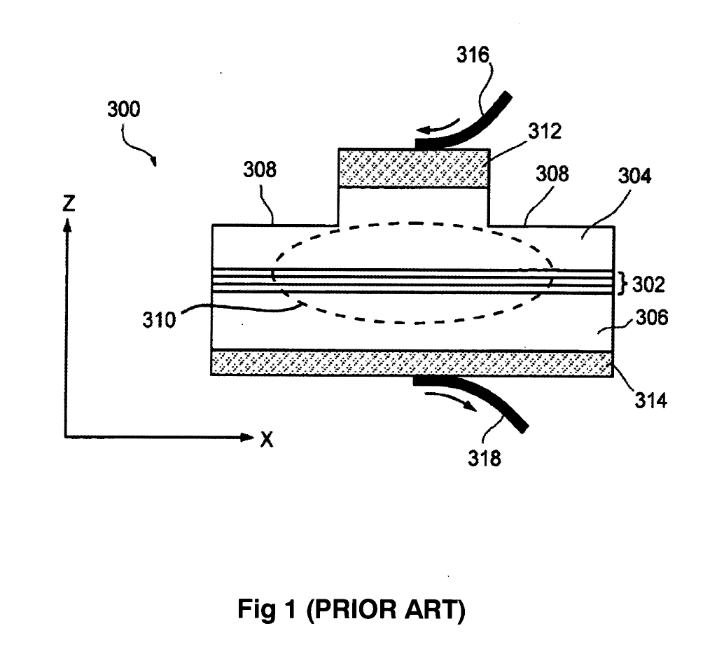

FIG. 1, adopted from application 20090135870, schematically shows a side cross-sectional view of an electrically driven semiconductor device 300 for two photon emission, using quantum wells as known in the art. The quantum wells of device 300 are located in layer 302, and consist of four periods of compressively strained Ga_{0.45}In_{0.55}P, each about 5 nm thick, separated by barriers of (Al_{0.5}Ga_{0.5})_{0.51}In_{0.49}P, each about 5.5 nm thick. Layer 302 is surrounded on top and bottom by layers 304 and 306 of AlGaInP cladding, which provide structural integrity for layer 302. The coordinate system in FIG. 1 is conveniently selected such that the layers are parallel to the x and y directions, and the z direction is along the growth direction of the layers.

Depressions 308 are etched into layer 304 on two sides, leaving a raised central ridge of about 4 microns wide. This configuration provides an effective lower index of refraction on the two sides, confining light emitted in layer 302 to a central region 310 of device 300. The emitted light is also confined vertically by the fact that the quantum well layer 302 has a higher index of refraction than cladding layers 304 and 306. As a result, the emitted light travels along the length of device 300, in a direction perpendicular to the plane of FIG. 1, and can be collected efficiently by photoreceivers located at one or both ends.

A cap 312, on top of cladding layer 304, made of heavily doped GaAs, and a similar heavily doped GaAs substrate 314 below cladding layer 306, provide electrical contacts respectively for electrical leads 316 and 318. The cap and substrate are coated with a thin layer of gold, to which the electrical leads are attached. Such heavily doped GaAs layers are often used as electrical contacts for semiconductor devices, because they do not oxidize as readily as a metal contact would. The p⁺ doping is optionally done with carbon that can reach densities greater than 10¹⁹ cm⁻³. This material is described, for example in Lemonias et al Journal of Vacuum Science & Technology B: Microelectronics and Nanometer Structures, March 1994, Volume 12, Issue 2, pp. 1190-1192. A thermoelectric cooler, in contact with the other side substrate 314, maintains device 300 at a temperature of about 300 K.

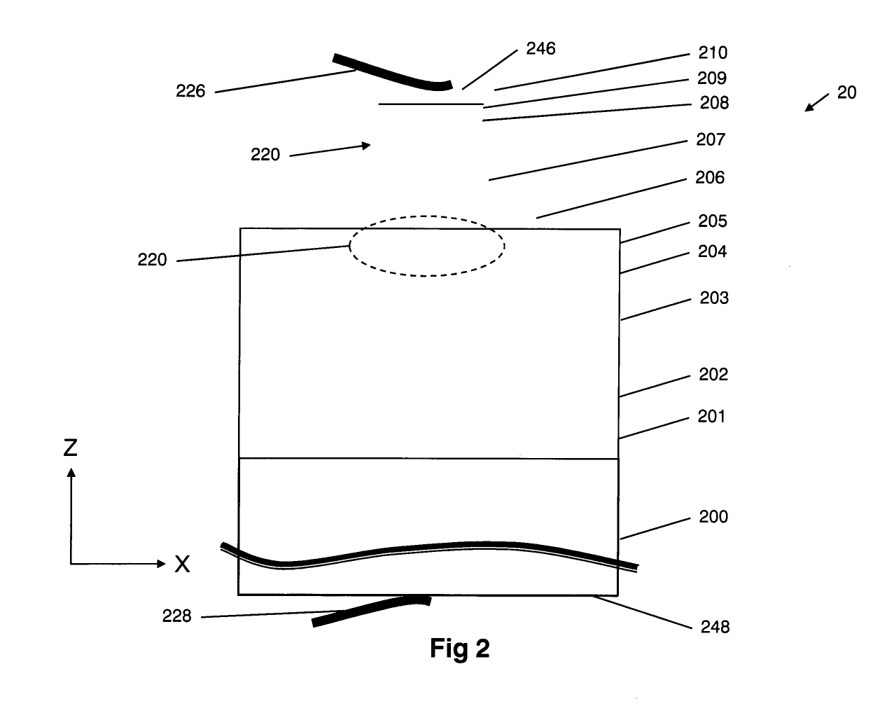

FIG. 2 schematically depicts a side view cross section of a semiconductor, room-temperature, electrically excited, two-photon device 20 having a thick optically active layer according to an exemplary embodiment of the current invention.

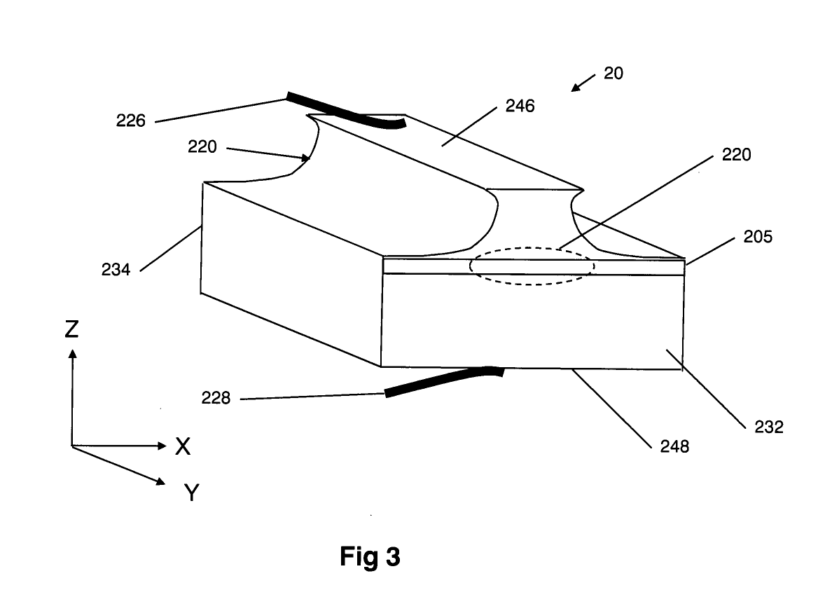

FIG. 3 schematically shows a perspective view of the device 20 shown in FIG. 2 according to an exemplary embodiment of the current invention.

According to exemplary embodiment of the invention, two-photon device 20 is epitaxially grown on substrate 200 and comprises multiple layers.

Table (see FIG. 6) depicts exemplary parameters of layers used in a device according to an embodiment of the current invention. It should be noted: these parameters are to be viewed as non-limiting example and that parameters such as: aluminum fraction and gradation; layer thickness; and doping type, material and concentration may be different. It should also be noted that some layer may be missing and additional layer may be added within the scope of the current invention.

In the exemplary embodiment of the current invention AlGaAs layers were epitaxially grown on GaAs substrate 200 using metalorganic chemical vapour deposition (MOCYD). However other methods of deposition may be used.

Optional Si doped GaAs buffer layer 201 was deposited over substrate 200.

Optional Si doped first graded layer 202 of AlₓGa₁₋ₓAs, with Al concentration varying from x=0 to x=0.6 was then deposited followed by Si doped n-cladding layer 203 of Al_{0.6}Ga_{0.4}As.

A highly confining single-mode slab waveguide in the growth direction is provided by first graded waveguide layer 204, the optically active layer 205 and second graded waveguide layer 206, which are preferably un-doped and sandwiched between n-cladding layer 203 and Zn doped p-cladding layer 207. The first graded waveguide layer 204 is made of AlₓGa₁₋ₓAs, with Al concentration x varying from x=0.6 to x=0.3.

The optically active layer 205 is a 0.5 micron thick layer of Al_{0.11}Ga_{0.89}As

The second graded waveguide layer 206 is made of AlₓGa₁₋ₓAs, with Al concentration x varying from x=0.3 to x=0.6.

P-cladding layer 207 is a Zn doped of Al_{0.6}Ga_{0.4}As.

The structure is completed by depositing a second graded layer 207 of Zn doped of AlₓGa₁₋ₓAs, with Al concentration varying from x=0.6 to x=0 optionally followed by Zn doped GaAs sub-contact layer 209 and Zn doped GaAs contact layer 210.

Lateral confinement was achieved by a ridge structure 220 formed by wet etching such that the ridge width varied nearly parabolically with height with corresponding grading of the effective index. It should be noted that other etching methods may be used, and other ridge widths, heights and profiles may be used within the scope of the current invention.

The combination of lateral (X) and vertical (Z) light confinements effectively confines the light to a single mode 220 propagation in Y direction as schematically depicted in FIGS. 2 and 3.

Optionally a metal layer such as gold is deposited on the top face 246 of the ridge 220 to which for electrical lead 226 is connected. Similarly, optionally a metal layer such as gold is deposited on the bottom face 248 of the substrate 200 to which for electrical lead 228 is connected.

Preferably, reflectivity at wavelength approximately corresponding to the band gape of the optically active layer of at least one of front facet 232 or back facet 234 (or both) is reduced to suppress undesired one-photon lasing. Reflectivity reduction may be achieved for example by coating with anti-reflection coating designed for the appropriate wavelength.

Alternatively, laser action may be suppressed by having a facet at an angle to ridge direction Y. Optionally; both facets may be at an angle to the ridge direction Y by shaping the device as a rhombus.

Depending on the applications, front facet 232 and/or back facet 234 may be coated or angled to control its reflectivity at the longer wavelength of two-photon working wavelength. Specifically angulations at Brewster angle may optionally be used.

Optionally, a heat-sink or a cooler such as Thermoelectric cooler may be thermally attached to the structure, preferably to bottom facet 248 to remove heat generated by electrical excitation currant provided between leads 226 and 228.

Exact parameters of the device may be chosen meet the device application. For example length (along the Y axis) may be selected to produce sufficient gain along the wave-guiding structure. The paper “Measurement of Optical Two-Photon Gain in Electrically Pumped AlGaAs at Room Temperature” to Amir Nevet, Alex Hayat, and Meir Orenstein; PRL 104, 207404 (2010) 21 May 2010 shows experimental results from the inventive device. For example device lengths of 0.8 and 0.8, 1.5 and 2.9 mm were investigated. However, shorter or longer devices may be used.

It is an advantage of the current device that the thickness of the optically active layer 205 is matched to the vertical extent of the optical mode 220. In the exemplary embodiment, the optically active layer 205 is 0.5 micron thick which is a substantial fraction of the 1.56 micron wavelength.

In contrast, the active layer of the device disclosed in United States patent application 20090135870 is only 42 nm (0.042 micron) thick.

Another optional advantage of the invention is the fact that no quantum wells need to be constructed in the inventive device. This may ease production, may increase yield and may reduce production cost.

According to an aspect of the current invention, a semiconductor p-i-n heterostructure based on AlGaAs layers may be specially designed to optimize the tightly guided optical mode confinement to the active gain region, as well as the two-photon nonlinear interaction length.

Since the two-photon transition probability is crystal momentum, k, dependent, the optimal active TPG layer of the semiconductor structure is preferably designed to have a band gap slightly narrower than 2 [symbol] ωₚ , where ωₚ is the photon angular frequency, enabling two-photon interaction with electrons at higher k values.

The design results in larger TPG relative to the parasitic effects; the latter are primarily free-carrier absorption and second harmonic generation in AlGaAs. This enables the observation of TPG, which could not have been achieved in the previous structure.

Moreover, the many-body effect of band gap renormalization can be exploited to obtain larger two-photon coefficient values γ₂, at TPG, compared to the absolute value at zero current (maximal two-photon absorption (TPA)), due to the band gap dependence of γ₂.

In TPG medium, the spatial change in the light intensity propagating in the z direction, neglecting higher order nonlinearities, is given by

dI/dz=Γγ′₂I²−αI,

where Γ is the confinement factor of the waveguide α, is the linear loss coefficient, and γ′₂ is the semiconductor TPG coefficient given by

$${γ}_{2}^{′} = \frac{8 {πω}_{p}}{{I}^{2}} {\sum }_{f} \int \frac{{d}^{2} k}{{( 2 π )}^{3}} [ {F}_{c} ( k ) - {F}_{u} ( k ) ] \times {\vert {\sum }_{n} \frac{〈 f \vert H \vert n 〉 〈 n \vert H \vert i 〉}{{E}_{n} - {E}_{i} - {ℏω}_{p}} \vert}^{2} ,$$

where F_{c}(k) and Fv(k) are the quasi-Fermi-Dirac distribution functions in the conduction and valence bands, respectively, and indices f, n, and i stand for the final, intermediate, and initial states accordingly.

$$H = - \frac{e}{m} \hat{p}$$

is the electron-radiation interaction Hamiltonian, where e is the electron charge, \hat{p} is the electron momentum operator, Â is the vector potential operator, and m is the electron mass, while energy conservation dictates E_{f}−Eᵢ=2 [symbol] ωₚ

Both α and γ′₂ depend on charge-carrier concentration n, where n dependence of α stems mainly from free-carrier absorption and that of γ′₂ from the separation of the quasi-Fermi levels E_{FC} and E_{FV} of the conduction and valence bands, respectively.

When the separation satisfies the two-photon population inversion condition: E_{FC}−E_{FV}>2 [symbol] ωₚ becomes positive resulting in TPG, while at lower carrier injection the gain is negative, corresponding to TPA. The solution for a device length L with an input intensity I₀ is

Iₒᵤₜ=I₀e^{-αL}/[1−γ₂I₀(1−e^{-αL})/α],

where γ₂ [symbol] Γγ′₂

Therefore, the output intensity exhibits concave dependence on input intensity for TPA (γ₂<0), linear dependence on input intensity for two-photon transparency (γ₂=0), and convex dependence on input intensity for TPG (γ₂>0).

Experiments were conducted on structure composed of 500 micron thick Al_{0.11}Ga_{0.89}As active layer having a band gap of 30 meV smaller than 2 [symbol] Ωₚ for 1.56 micron wavelength.

Due to band-gap renormalization during the flow of current through the device, the effective band-gap energy may be further reduced, for example to be 50 meV smaller than the sum energies of the two emitted photons.

When TPG at other photon energies is desired, the band-gap energy of the optically active layer may be selected to be approximately between 1.5 to 7 percents lower than the sum energies of the two photons. This can be achieved by selecting the aluminum concentration in the optically active layer. For different photon energy ranges, other electro-optically active semiconductor materials may be chosen.

It should be noted that experiments were performed in room temperature. However, band-gap energies changes with temperature and with electrical excitation. Similarly, the difference between the bang-gap and the sum energies of emitted photons may also depends on temperature and electrical excitation.

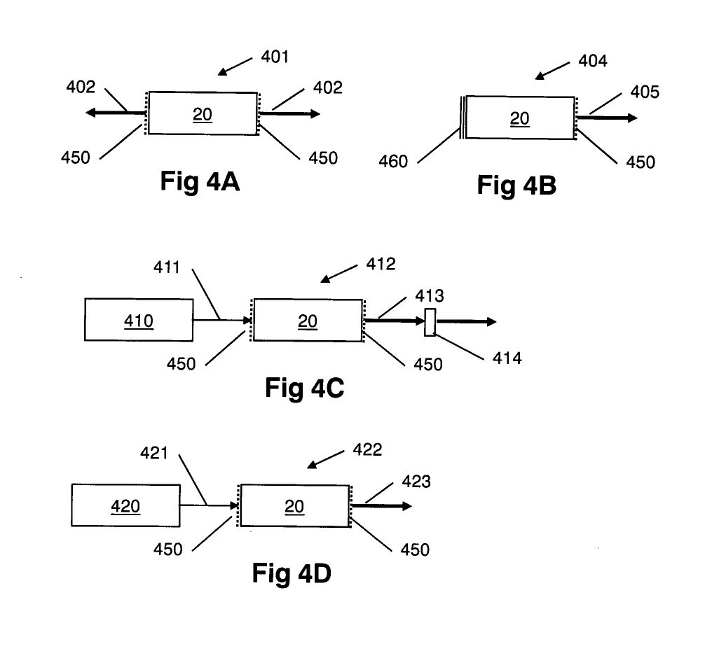

FIGS. 4A-D schematically depicts some exemplary applications of a semiconductor, room-temperature, electrically excited, two-photon device with large active region 20 according to exemplary embodiments of the current invention. It should be noted that device 20 may be used in other applications within the scope of the current invention. For examples device 20 may be used in the applications disclosed in United States patent application 20090135870, replacing the electrically driven semiconductor device for two photon emission, using quantum wells disclosed in that application.

For clarity, mode matching optics and other optical elements may have been removed from these drawings.

FIG. 4A schematically depicts a bright source 401 of broad wavelength, infrared radiation according to an exemplary embodiment of the current invention.

In this exemplary embodiment, device 20 may be used as a bright source 401 of broad wavelength, infrared radiation. In this embodiment, both front and back facets of device 20 are coated with anti-reflection coating 450 such that two opposing output beams 402 are produced. Current between leads 226 and 228 of device 20 creates electrons and holes in active layer 205. Spontaneous two-photon emission creates infra-red (IR) radiation in the active layer. The wave guiding properties of device 20 causes a substantial fraction of the radiation to exit as output beams 402.

FIG. 4B schematically depicts a bright source 404 of broad wavelength, infrared radiation according to another exemplary embodiment of the current invention.

In this exemplary embodiment, device 20 may be used as a bright source 404 of broad wavelength, infrared radiation. Current between leads 226 and 228 of device 20 creates electrons and holes in active layer 205. Spontaneous two-photon emission creates infra-red (IR) radiation in the active layer. The wave guiding properties of device 20 causes a substantial fraction of the radiation to be confined and to travel along the Y axis. In this embodiment, front facet of device 20 is coated with anti-reflection coating 450, while the back facet is coated with high reflectivity coating 460. Radiation in traveling towards the back facet is reflected such that only one output beam 405 is produced. Beam 405 is thus more intense than any of beams 402.

FIG. 4C schematically depicts a broad wavelength optical gain device according to another exemplary embodiment of the current invention.

Device 20 has an inherently very broad wavelength gain. When used as a small signal optical amplifier 412 for wavelength away from the central wavelength, it will exhibit gain over broad spectral range. However, it should be noted that idler radiation is produced due to the two photon induced emission. This radiation may optionally be filtered out. Due the broad spectral range this amplifier may have very fast response time and is capable of amplifying very short pulses.

In this exemplary embodiment, device 20 may be used as a fast, broad wavelength, optical amplifier 412. Signal source 410, for example free space or fiber optic communication system or other weak signal source feeds signal 411 to device 20. In this embodiment, both front and back facets of device 20 are coated with anti-reflection coating 450. Optional optical filter 414 may be used to remove idler radiation photons from amplified output beam 413.

FIG. 4D schematically depicts a non-linear optical amplifier and pulse compressor 422 according to another exemplary embodiment of the current invention.

In this application a short pulse at central wavelength is fed into device 20. At central wavelength, device 20 exhibits non-linear amplification due to the doubly induced two-photon emission process. Thus, for a short pulse propagating in a two-Photon gain medium, the high-intensity peak of the pulse is amplified more than the low-intensity tails, resulting in pulse compression.

Two photon gain device combines both: extremely wideband homogeneous spectrum related to the very fast lifetime of the virtual state, and a very strong nonlinearity based on second-order resonant transitions.

Pulse compression by two photon gain device may be achieved in a miniature electrically-pumped device 20, this in contrast to pulse compression using non-linear loss by saturable absorbers.

In this exemplary embodiment, device 20 may be used as a fast, non-linear, pulse compressor and optical amplifier 422. Signal source 420, for example a mode locked laser feeds short pulses 421 to device 20. In this embodiment, both front and back facets of device 20 are coated with anti-reflection coating 450. Amplified and compressed pulses exit at output beam 423.

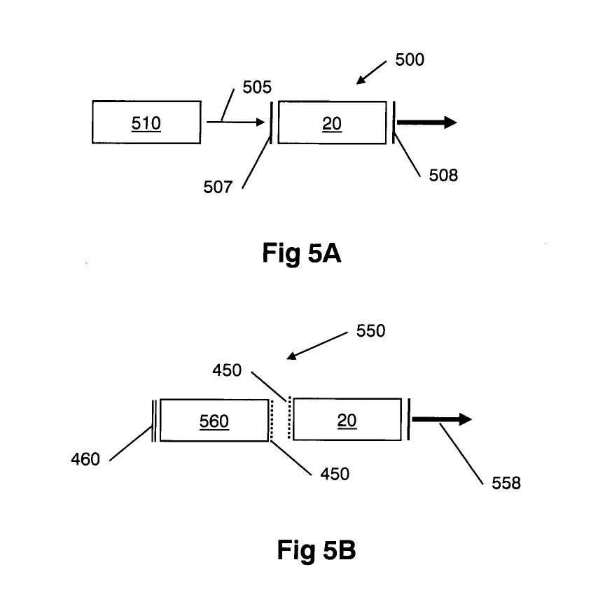

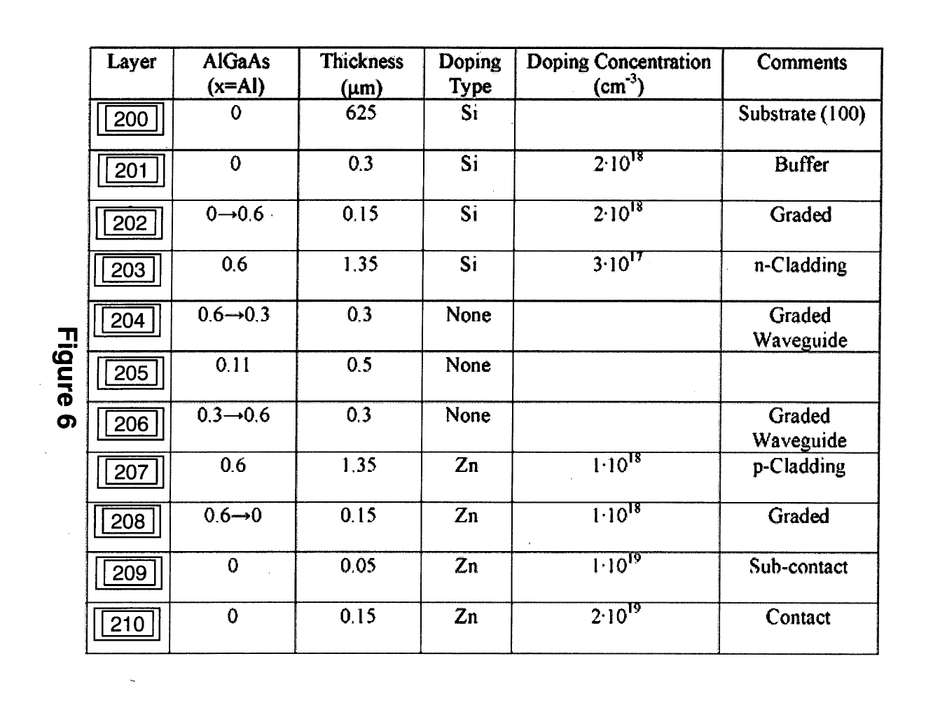

FIG. 5A schematically depicts an externally seeded two-photon laser 500 according to an exemplary embodiment of the current invention.

A two-photon lasing may require seeding to generate sufficient initial intensity for sufficient two-photon gain to overcome cavity loses.

Seeding may be achieved using for example a pulsed semiconductor laser. For example for seeding a two-photon laser at wavelength of 1.55 micron, a pulsed laser of InGaAs/InAs on InP may be used. Alternatively, other lasers may be used.

In the depicted embodiment, one-photon seeding laser 510 provides seeding beam 505 to the two-photon laser 500. Two-photon laser 500 comprises a two-photon gain device 20 within an optical cavity made of two partially-reflecting mirrors 507 and 508.

Mirrors 507 and/or 508 may be deposited on facets of device 20, or may be external to the device.

It should be noted that other cavity configurations, for example configurations comprising wavelength selection devices or cavity length matching devices may be used.

FIG. 5B schematically depicts an internally seeded two-photon laser 550 according to another exemplary embodiment of the current invention.

In the depicted embodiment, seeding of laser 550 is provided by adding a one-photon gain device 560 within the same cavity. In the depicted embodiment, the cavity is formed between a high reflectivity mirror 460 and partially reflecting mirror 508 through which the output beam 558 exits. In the depicted embodiment, high reflectivity mirror 460 and partially reflecting mirror 508 are deposited on back facet of one-photon device 560 and front facet of two-photon device 20. However, other configurations may be used. Preferably, the inward facing facets are coated with anti-reflection coating 450 to reduce cavity losses.

It should be noted that other cavity configurations, for example configurations comprising wavelength selection devices or cavity length matching devices may be used.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims. All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention.

1. A method of manufacturing a semiconductor, room-temperature, electrically excited, two-photon device comprising at least the steps of:
a. providing a substrate;
b. epitaxially growing a first, doped, cladding layer;
c. epitaxially growing a first, graded wave-guiding layer;
d. epitaxially growing an intrinsic optically active layer;
e. epitaxially growing a second, graded wave-guiding layer;
f. epitaxially growing a second cladding layer doped with opposite doping type as the first cladding layer;
g. etching a ridge in the structure to create a linear wave-guide; and
h. connecting leads for providing electrical current through said optically active layer, wherein the thickness of said optically active layer is at least 10 percent of the thickness of the optical mode confined by the wave-guiding layers.

2. The method as claimed in claim 1, wherein the thickness of said optically active layer is at least 20 percent of the thickness of the optical mode confined by the wave-guiding layers.

3. The method as claimed in claim 2, wherein the thickness of said optically active layer is at least 40 percent of the thickness of the optical mode confined by the wave-guiding layers.

4. The method as claimed in claim 3, wherein said substrate is doped GaAs substrate.

5. The method as claimed in claim 4, wherein said first cladding layer is Si doped AlGaAs, and said second cladding layer is Zn doped AlGaAs.

6. The method as claimed in claim 5, wherein said optically active layer is an intrinsic AlGaAs having Al concentration lower than Al concentration in said first and second cladding layers.

7. The method as claimed in claim 6, and further comprising the step of:
a) epitaxially grow on said substrate a Si doped buffer layer;
b) epitaxially grow on said buffer layer a first Si doped graded layer;
c) epitaxially grow on said second cladding layer a second Zn doped graded layer; and
d) epitaxially grow on said second graded layer a Zn doped contact layer.

8. The method as claimed in claim 4, wherein thickness of said optically active layer is at least 0.2 microns.

9. The method as claimed in claim 8, wherein thickness of said optically active layer is at least 0.4 microns.

10. A semiconductor, room-temperature, electrically excited, two-photon device comprising:
e) a substrate;
f) a first doped cladding layer;
g) a first graded wave-guiding layer adjacent to said first cladding layer;
h) an intrinsic optically active layer adjacent to said first graded wave-guiding layer;
i) a second graded wave-guiding layer adjacent to said optically active layer;
j) a second cladding layer doped with opposite doping type as the first cladding layer adjacent to said second graded wave-guiding layer;
k) a ridge etched in the structure to creating a linear wave-guide; and
l) leads, capable of providing electrical current through said optically active layer, wherein the thickness of said optically active layer is at least 10 percent of the thickness of the optical mode confined by the wave-guiding layers.

11. The device as claimed in claim 10, wherein the thickness of said optically active layer is at least 20 percent of the thickness of the optical mode confined by the wave-guiding layers.

12. The device as claimed in claim 11, wherein the thickness of said optically active layer is at least 40 percent of the thickness of the optical mode confined by the wave-guiding layers.

13. The method as claimed in claim 10, wherein said substrate is doped GaAs substrate.

14. The device as claimed in claim 13, wherein said first cladding layer is Si doped AlGaAs, and said second cladding layer is Zn doped AlGaAs.

15. The device as claimed in claim 14, wherein said optically active layer is an intrinsic AlGaAs having Al concentration lower than Al concentration in said first and second cladding layers.

16. The device as claimed in claim 15, and further comprising:
m) Si doped buffer layer adjacent to said substrate;
n) a first Si doped graded layer between said buffer layer and said first cladding layer;
o) a second Zn doped graded layer adjacent to said second cladding layer; and
p) a Zn doped contact layer.

17. The device as claimed in claim 10, wherein thickness of said optically active layer is at least 0.2 microns.

18. The device as claimed in claim 17, wherein thickness of said optically active layer is at least 0.4 microns.

19. The device as claimed in claim 10, wherein at least one end of said linear wave-guide is coated with an anti-reflection coating, and said device is capable of producing broad spectrum infrared radiation by two-photon spontaneous when electrical current is applied between said leads.

20. The device of claim 19, wherein both ends of said linear wave-guide are coated with an anti-reflection coating.

21. The device of claim 19, wherein second end of said linear wave-guide is coated with a high reflectance coating.

22. The device as claimed in claim 10, wherein both end of said linear wave-guide are coated with an anti-reflection coating, and said device is capable of producing broad spectrum gain by two-photon stimulated emission when electrical current is applied between said leads.

23. The device of claim 22, the device is capable of producing non-linear gain of an input signal when said input signal is substantially at central wavelength of said broad spectrum gain.

24. The device of claim 23, the device is capable of producing pulse shortening when said input signal is in a form of a short pulse.

25. The device as claimed in claim 10, further comprising two cavity mirrors, each positioned to reflect light back into one ends of said guide, such that the device is capable producing two-photon lasing when current is applied between said leads.

26. The device as claimed in claims 25, further comprising a one-photon laser capable of producing coherent radiation, wherein said one-photon laser is external to the cavity formed by said two cavity mirrors and is capable of seeding said two-photon lasing action.

27. The device as claimed in claims 25, and further comprising a one-photon gain device internal to the cavity formed by said two cavity minors and is capable of seeding said two-photon lasing action.
